(19) United States
(12) Patent Application Publication
(10) Pub. No.: US 2021/0009723 A1
(43) Pub. Date: Jan. 14, 2021

(54) Acid-Labile, Crosslinked Polymers, Compositions and Methods of Their Use

(71) Applicants: Daniel J. Nawrocki, Chicopee, MA (US); Jenna Cordero, Marlborough, MA (US); Kristina Markt, N. Grafton, MA (US)

(72) Inventors: Daniel J. Nawrocki, Chicopee, MA (US); Jenna Cordero, Marlborough, MA (US); Kristina Markt, N. Grafton, MA (US)

(21) Appl. No.: 16/506,751

(22) Filed: Jul. 9, 2019

(51) Int. Cl. C08F 12/24; G03F 7/039; G03F 7/038; G03F 7/16; G03F 7/20; G03F 7/38; G03F 7/32; G03F 7/40

(52) U.S. Cl. CPC C08F 12/24; G03F 7/0392; G03F 7/0382; G03F 7/162; G03F 7/40; G03F 7/2004; G03F 7/38; G03F 7/322; G03F 7/168

(57) ABSTRACT

The invention relates to acid-labile, crosslinked polymers. More specifically, the invention relates to acid-labile, crosslinked polymers useful in photosensitive compositions as well as method of their use in photoresist applications

### FIELD OF INVENTION

The invention relates to acid-labile, crosslinked polymers. More specifically, the invention relates to acid-labile, crosslinked polymers useful in photosensitive compositions as well as method of their use in photoresist applications

### BACKGROUND OF THE INVENTION

The present invention is directed to photoresist compositions suitable for the manufacture of integrated circuits.

Photoresists are photosensitive films for transfer of an image to a substrate for use in the manufacture of integrated circuits. An integrated circuit (IC) is a set of electronic circuits that are manufactured onto a semiconductor, notably silicon. ICs can be made very compact, having upwards of 10 million transistors or other electronic components per mm² and growing. As such the width and size of the conducting lines and interconnections used to connect the transistors and other components to the rest of the microcircuit need to be made smaller and smaller as the technology advances, currently tens of nanometers.

Photoresists form negative or positive images. After coating a photoresist coating composition onto a substrate, the coating is exposed through a patterned photomask to actinic radiation such as ultraviolet light to form a latent image in the coating. The photomask has areas both opaque and transparent to activating radiation that define a desired image to be transferred to the underlying substrate. A relief image is provided by development of the latent image pattern in the resist coating.

Currently, chemically amplified photoresist compositions have been developed to address the need for faster, higher resolution photoresist to allow the manufacture of smaller and smaller integrated features. Chemically amplified photoresists may be negative or positive-acting and rely on many crosslinking events (in the case of a negative-acting resist) or deprotection reactions (in the case of a positive-acting resist), each catalyzed by photogenerated acid or base. In the case of the positive chemically amplified resist, photoinitiators capable of yielding a photogenerated acid have been used to induce cleavage of acid-labile functionalities pendant from a photoresist polymer binder. Upon exposure of a photoresist coating and a post exposure bake, selected cleavage of the blocking group results in formation of a polar functional group, e.g., hydroxyl, carboxyl or imide. The generation of a polar functional group provides for solubility in aqueous developers such as TMAH (tetramethyl ammonium hydroxide).

Positive photoresist compositions are processed by coating the composition, drying to desired thickness, exposing the composition to actinic radiation, optionally post exposure baking, and removing the exposed areas using a developer. Typically, exposing positive photoresists to actinic radiation creates areas which are soluble in alkaline solutions. However, the photoresist process is not entirely efficient in that the parts of exposed areas are not completely soluble in the alkaline developer, so that longer developer times, higher development temperatures, higher concentrations of base in the developer are required to cleanly remove the exposed photoresist. Each of these aggressive development parameters can have a deleterious effect on the unexposed photoresist, thereby degrading the pattern used to create the integrated circuit. Additionally, current integrated circuit technology has standardized the integrated circuit process, requiring specific developers, tetramethylammonium hydroxide, a specific concentration 2.38% in water, and times. As such compositions need to meet these conditions while maintaining complete integrity of the photopattern desired. Standardization is also present in the exposure process, particularly time. Integrated circuit technology continues to trend to smaller and smaller lines which can be addressed by thinner coatings on the photoresist compositions on a substrate, further requiring that the unexposed pattern is unaffected by strong developer condition and allowing higher resolution. As such, there is a delicate balance required of the photoresist composition.

Thus, there is a need for improved materials and improved processes that are designed to meet the new and ever demanding integrated circuit technology, particularly in the area of positive-acting photoresist compositions, materials and methods that allow fast exposure, thin coating, higher resolution, proper development capabilities, and minimal attack of the unexposed photopattern.

### DESCRIPTION OF THE FIGURES

FIG. 1 shows a general structure of the internally crosslinked polymer of the current disclosure.

FIG. 2 show a schematic of a typical synthesis of the internally crosslinked polymers of the current disclosure.

FIG. 3 shows chemical structures of examples of photoacid generators useful in the current disclosure.

FIG. 4 is jpeg of an optical microscope picture taken from the photopattern of the process of Example 2.

FIG. 5 is a jpeg of an SEM taken from the photopattern of the process of Example 6.

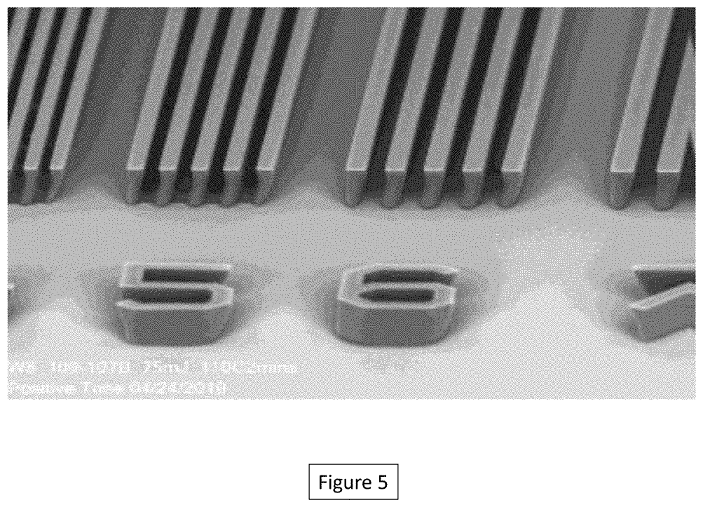

### SUMMARY OF EXEMPLARY EMBODIMENTS

Disclosed and claimed herein are polymers suitable for positive and negative photoresist compositions for the manufacture of integrated circuits which are formed from the internal crosslinking of at least 2 polymer segments. The polymer segments are comprised of phenol groups which are obtained by the reaction of hydroxystyrene in the polymerization process. The amount of phenol in the polymer segments range from about 5% to about 100%. The polymer segments are internally crosslinked via the pendent hydroxy groups from the phenols of the hydroxystyrene contained in the polymer segments. The internally crosslinked polymer can be used alone in photoresist compositions and photoresist methods, or they may be blended with other polymers, oligomers, or copolymers designed for balancing the solubility of the composition in alkaline developer to obtain high resolution, high aspect ratio and well defined features resulting from the photoresist process.

In a first embodiment, disclosed and claimed herein is a polymer containing two or more polymer segments, each polymer segment containing hydroxystyrene in the polymer segment backbone, wherein the polymer segments are internally crosslinked via hydroxy functionalities of the hydroxystyrenes by at least one di-functional crosslinker to form a polymer containing acid labile crosslinks.

In a second embodiment, disclosed and claimed herein is the polymer of the above embodiment, wherein the acid labile crosslinks are acetals, ketals, carboxylic acid esters, silyl esters, methylene-ethers, ortho-esters crosslinks or combinations thereof.

In a third embodiment, disclosed and claimed herein are polymers of the above embodiments, wherein the di-functional crosslinker is a difunctional aliphatic group, a cycloaliphatic group, an aryl group, a fused aryl group, an aliphatic heterocyclic group, an aromatic heterocyclic group, or combinations thereof.

In a fourth embodiment, disclosed and claimed herein are the polymers of any of the above embodiments, wherein the polymer segments further comprise at least one additional monomer unit in the polymer segment backbone which include for example at least a substituted or unsubstituted styrene monomer unit, a substituted or unsubstituted hydroxystyrene monomer unit, or both.

In a fifth embodiment, disclosed and claimed herein are the polymers of any of the above embodiments, wherein the hydroxy functionality of the additional hydroxystyrene monomer unit is further functionalized by a mono acetal or ketal.

In a sixth embodiment, disclosed and claimed herein are the polymers of any of the above embodiments, wherein the percent of hydroxy functionalities that are crosslinked is between about 2% and about 5%, wherein the percent of hydroxy functionalities are reacted with mono acetal or ketal is between about 20% and about 40% or both.

In a seventh embodiment, disclosed and claimed herein are photoresist compositions containing a polymer of any one of the above embodiments, at least one photoacid generator and at least one solvent, and may further contain a surfactant, an adhesion promoter, a dissolution inhibitor, a dye or combinations thereof.

In an eighth embodiment, disclosed and claimed herein are photoresist compositions of the above embodiment, wherein the at least one photoacid generator is, for example, an onium salt compounds, a sulfone imide compound, a halogen-containing compound, a sulfone compound, a sulfonate ester compound, a quinine-diazide compound, or a diazomethane compound and wherein the at least one solvent comprises esters, ethers, ether-esters, ketones, keto-esters, hydrocarbons, aromatics, and halogenated solvents and combinations thereof.

In a ninth embodiment, disclosed and claimed herein are methods of patterning the photoresist compositions of the above embodiments by providing a substrate, applying the photoresist compositions of any of the above embodiments to a desired wet thickness, heating the coated substrate to remove a majority of the solvent to obtain a desired thickness, imagewise exposing the coating to actinic radiation, post exposure baking the imaged coating, removing the unexposed areas of the coating, and optionally heating the remaining coating.

In further embodiments, disclosed and claimed herein are photoresist compositions and methods of the above embodiments wherein the compositions further comprise at least one of a non-crosslinked polymer, oligomer, or copolymer, wherein the at least one non-crosslinked polymer, oligomer or copolymer has selected solubility in alkaline developer.

In further embodiments disclosed and claimed herein are photoresist compositions and methods wherein the at least one polymer, oligomer or copolymer is comprised of monomers chosen from styrene, hydroxystyrene, acrylic acid, acrylic esters, phenols, polyhydroxyphenyls, ethers, hydroxystyrene esters, or combinations thereof.

### DETAILED DESCRIPTION

We have surprisingly found that internally crosslinking polymer segments of the current disclosure, essentially doubling the molecular weight or higher, provides photoresist compositions with 0% dissolution of the unexposed coating during typical developer conditions, also known in the industry as “film loss”, while providing excellent solubility in standard developer and development schemes, provided high exposure speeds and excellent resolutions.

As used herein, the conjunction “and” is intended to be inclusive and the conjunction “or” is not intended to be exclusive unless otherwise indicated. For example, the phrase “or, alternatively” is intended to be exclusive.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

A used herein the term “polymer segment” refers to a polymer unit which is crosslinked to another polymer unit to result in the polymer made up of at least 2 polymer segments, and in some embodiments more than two. The polymer segments are polymers in their own right and contain hydroxystyrene in their backbones. The amount of hydroxystyrene in the backbone of the polymer segments may vary from about 10% to essentially 100%. Two or more of the segments are then crosslinked (joined) internally through a hydroxystyrene group, one from each polymer segment, by a di-functional crosslinker to form the polymer of the current disclosure.

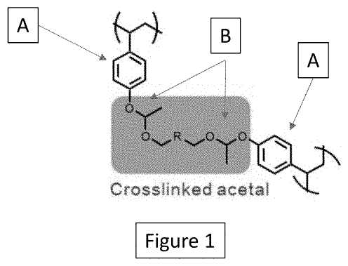

Disclosed and claimed herein is a polymer containing two or more polymer segments, each polymer segment containing hydroxystyrene in the polymer segment backbone, wherein the polymer segments are internally crosslinked via hydroxy functionalities of the hydroxystyrenes by at least one di-functional crosslinker to form a polymer containing acid labile crosslinks and shown in FIG. 1, where A are the polymer segment, B are acid labile groups and R is the disubstituted ballast group that crosslinks the polymer segments A.

“Internal crosslinking” is herein defined as the crosslinking of two or more polymer segments. Distinguished in that the crosslinking is not end-to-end of the polymer segments which merely extends the chain lengthwise. The polymer segments are linked via reactive groups internally pendent along the chain of each the polymer segment, such as, for example, hydroxy groups. Internal crosslinking may occur more than once between two polymer segments. For example, two crosslinks may occur between two polymer segments, wherein the polymer segments are linked in two positions along the respective chains, essentially forming a cyclic polymeric material. Internal crosslinking may also occur between more than two polymer segments. For example, one crosslink may occur between two polymer segments and a second crosslink may occur between one of the crosslinked polymer segments with a third polymer segment. Other internal crosslinks of the current disclosure include multiple crosslinks between two polymer segments along with crosslinks to one or more other polymer segments. There is no limit to the number of crosslinks that may occur between two polymer segments and/or other polymer segments. The number of internal crosslinks can be chosen during synthesis to provide chosen desirable polymer properties such as those chosen for a variety of electronic application, such as, for example, molecular weight, dissolution rate in the chosen developer, solubility in solvent or developer, film forming characteristics, resolution capabilities and the like. The number of crosslinks are also chosen to allow a desired amount of developer soluble functionalities, such as hydroxy groups, remaining in the polymer.

The crosslinks connecting the polymer segments suitable for the current disclosure are acid-labile, in that when the crosslinks are exposed to acid they breakdown via hydrolysis, or other reaction mechanisms, to provide fully or partially the original phenol functionality of the original polymer segment. The desired number of acid-labile groups that breakdown will depend on the amount of resultant developer soluble functionalities needed to allow development within the time and developer conditions of the required IC process.

The current disclosure uses polymer segments contain hydroxystyrene in the polymer segment backbone, either alone or co-polymerized with one or more other vinyl or acrylate monomers, including, for example, substituted or unsubstituted styrenes, acrylates, methacrylates, vinyl ethers, and the like. The type and amount of additional monomers as copolymer for the polymer segments of the current disclosure are chosen to provide various required film and photoresist characteristics for IC manufacture, such as, for example, high resolution, high aspect ratio, straight structural sidewalls and clean development of structural spaces. For example, addition of styrene monomer to the polymer segment backbone reduces the amount of hydroxy in the resultant crosslinked polymer thereby reducing developability, as well as increasing polymer mechanical strength, viscosity and the like. For example, the molecular weight of the crosslinked polymer may be between about 5,000 and about 75,000 Daltons.

As mentioned the hydroxy functionalities of the current polymer segment are used to crosslink with di-functional crosslinkers chosen so that the resulting crosslink between the polymer segment and the crosslinker will be acid labile.

As used herein the term acid labile crosslink refers to a functionality which reacts when exposed to an acid to break down. In the current disclosure the acid labile crosslink breaks down on exposure to acid to at least the hydroxy functionality that was originally pendent on the polymer segment, thus allowing an increase in the ability of the polymer, and thus the photoexposed coating, to dissolve in the developer.

Acid-labile crosslinks useful for the current disclosure include, for example, but not limited to, acetals, ketals, carboxylic acid esters, silyl esters, methylene-ethers, ortho-esters, polyethers, or combinations thereof, with the requirement that the resultant crosslink is acid labile, able to break down when exposed to acid. Suitable examples of acid-labile groups which decompose in the presence of an acid to produce aromatic hydroxy groups include alkoxyalkyl ether groups, tetrahydrofuranyl ether groups, tetrahydropyranyl ether groups, tert-alkyl ester groups, trityl ether groups, silyl ether groups, alkyl carbonate groups as for example tert-butyloxycarbonyloxy-, trityl ester groups, silyl ester groups, alkoxymethyl ester groups, cumyl ester groups, acetal groups, ketal groups, tetrahydropyranyl ester groups, tetrafuranyl ester groups, tertiary alkyl ether groups, tertiary alkyl ester groups, and the like. Examples of such group include alkyl esters such as methyl ester and tert-butyl ester, acetal type esters such as methoxymethyl ester, ethoxymethyl enter, 1-ethoxyethyl ester, 1-isobutoxyethyl ester, 1-isopropoxyethyl ester, 1-ethoxypropyl ester, 1-(2-methoxyethoxy) ethyl ester, 1-(2-acetoxyethoxy)ethyl ester, 1-[2-(1-adamantyloxy) ethoxy]ethyl ester, 1-[2-(1-adamantylcarbonyloxy)ethoxy]ethyl ester, tetrahydro-2-furyl ester and tetrahydro-2-pyranyl ester, and alicyclic ester such as isobornyl ester.

The crosslinker of the current disclosure is difunctional, in that the crosslinker contains two functionalities, such as disclosed above that will react with the polymer segments to create linkages that are acid labile. The crosslinker is essentially made up of a ballast group to which the two suitable functional groups are attached, such as, for example, a 1,4-bis(vinyloxymethylene) cyclohexane (1) in which 1,4-methylenecyclohexane is the ballast group:

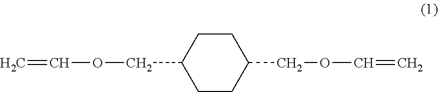

In this example the hydroxy group from the styrene monomer of the polymer segment adds across the vinyl double bond to create an acetal (2), in this example R=1,4-cyclohexane:

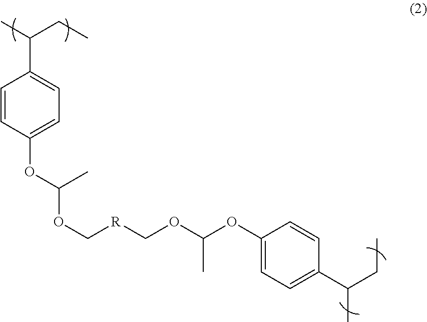

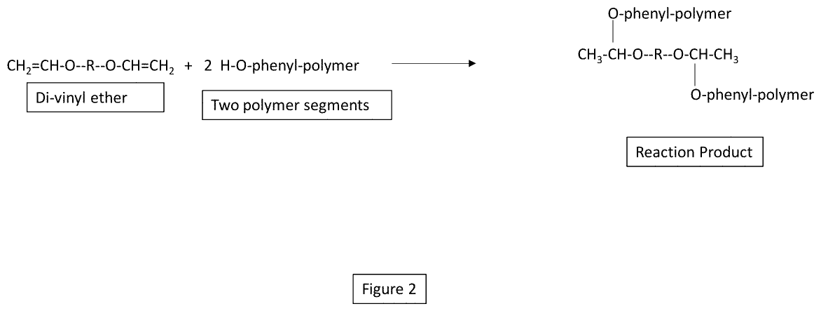

One example of the preparation of these polymers is shown in the scheme of FIG. 2.

Ballast groups useful for the current disclosure are chosen for their characteristics that are useful in the photoresist process in IC manufacture, such as, for example molecular weight, dissolution rate in the chosen developer, solubility in solvent or developer, film forming characteristics, resolution capabilities, viscosity, mechanical strength and the like. The ballast groups are difunctional and include, for example, but are not limited to substituted of unsubstituted ballast groups such as aliphatic groups, cycloaliphatic groups, aryl groups, fused aryl groups, aralkyl groups, aliphatic heterocyclic groups, aromatic heterocyclic groups, or combinations thereof. The ballast groups may be monomeric, oligomeric or polymeric.

In embodiments wherein additional hydroxystyrene monomer units are present in the polymer backbone of the polymer segments, the hydroxy group may be functionalized by a mono functional acid labile groups, such as those disclosed above. The amount of functionalization is chosen again for their characteristics in creating photoresist compositions and photoresist processes, such as, for example, developability and developer resistance.

The polymers of the current disclosure may be crosslinked from between about 2% and about 5%, while the percent of hydroxy functionalities that are reacted with mono acetal or ketal may be between about 20% and about 40%.

Disclosed and claimed herein are photoresist compositions containing one or more of the polymers described above, at least one photoacid generator, and at least one solvent.

Further disclosed and claimed herein are photoresist compositions described above which are blended with additional polymers, oligomers and/or copolymers. Such polymers, oligomers and/or copolymers are blended to provide improved photoresist characteristics, such as, for example, developability by the additional of developer soluble additional polymers, and improved resulting photoresist patterns, such as improved photosensitivity, improved aspect ratio, improved pattern integrity, improved clean-out of spaces between the patterns, and the like. By careful blending of the internally crosslinked polymers of the current disclosure with an additional polymer, oligomer or copolymer as described above, high resolution, high aspect ratio, high photopattern integrity, high developability, high resistance to the developer in non-exposed areas, high resist removal from the spaces in the pattern, and the like can be achieved.

Examples of additional polymers, oligomers and co-polymers suitable for the photoresist compositions which are soluble in the developer disclosed and claimed herein include, polymers, oligomers and/or copolymers comprised of substituted or unsubstituted monomers chosen from styrene, hydroxystyrene, acrylic acid, methacrylic acid acrylic esters such as hydroxyethylacrylate, methacrylic esters such as hydroxyethylmethacryate, phenols, polyhydroxyphenyls such as pyrogallol and resorcinol, ethers such as alkyl ethers of vinyl alcohol, hydroxystyrene esters, or combinations thereof. A polymer soluble in an aqueous alkaline developer useful in the present invention include novolak resins, hydrogenated novolak resins, acetone-pyrogallol resins, poly(o-hydroxystyrene), poly(m-hydroxystyrene), poly(p-hydroxystyrene), hydrogenated poly(hydroxystyrene)s, halogen- or alkyl-substituted poly (hydroxystyrene)s, hydroxystyrene/N-substituted maleimide copolymers, o/p- and m/p-hydroxystyrene copolymers, partially o-alkylated poly(hydroxystyrene)s, for example, o-methylated, o-(1-methoxy)ethylated, o-(1-ethoxy)ethylated, o-2-tetrahydropyranylated, and o-(t-butoxycarbonyl)methylated poly(hydroxystyrene)s having a degree of substitution of from 5 to 30 mol % of the hydroxyl groups, o-acylated poly(hydroxystyrene)s for example, o-acetylated and o-(t-butoxy)carbonylated poly(hydroxystyrene)s having a degree of substitution of from 5 to 30 mol % of the hydroxyl groups, styrene/maleic anhydride copolymers, styrene/hydroxystyrene copolymers, α-methylstyrene/hydroxystyrene copolymers, carboxylated methacrylic resins, and derivatives thereof. Further suitable are poly (meth)acrylic acid, for example, poly(acrylic acid)], (meth)acrylic acid/(meth)acrylate copolymers, for example, acrylic acid/methyl acrylate copolymers, methacrylic acid/methyl methacrylate copolymers or methacrylic acid/methyl methacrylate/t-butyl methacrylate copolymers, (meth)acrylic acid/alkene copolymers, for example, acrylic acid/ethylene copolymers], (meth)acrylic acid/(meth)acrylamide copolymers, for example acrylic acid/acrylamide copolymers, (meth)acrylic acid/vinyl chloride copolymers, for example, acrylic acid/vinyl chloride co-polymers, (meth)acrylic acid/vinyl acetate copolymer, for example, acrylic acid/vinyl acetate copolymers], maleic acid/vinyl ether copolymers, for example, maleic acid/methyl vinyl ether copolymers, maleic acid mono ester/methyl vinyl ester copolymers, for example, maleic acid mono methyl ester/methyl vinyl ether copolymers, maleic acid/(meth)acrylic acid copolymers, for example, maleic acid/acrylic acid copolymers or maleic acid/methacrylic acid copolymers, maleic acid/(meth)acrylate copolymers, for example, maleic acid/methyl acrylate copolymers, maleic acid/vinyl chloride copolymers, maleic acid/vinyl acetate copolymers and maleic acid/alkene copolymers, for example, maleic acid/ethylene copolymers and maleic acid/1-chloropropene copolymers.

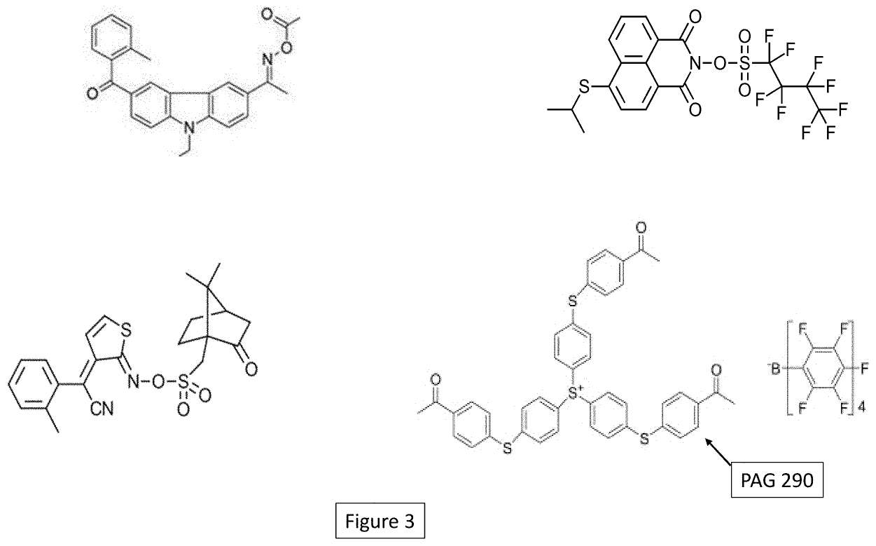

Photoacid generators useful in the current disclosure are well known on the photoresist industry and include, for example, but are not limited to, onium salt compounds, sulfone imide compounds, halogen-containing compounds, sulfone compounds, sulfonate ester compounds, quinine-diazide compounds, or diazomethane compounds. Some specific examples of photoacid generators useful in the current disclosure include SP606, 1-651, 1-819 and 1-379 and those listed in FIG. 3. The photoacid generators may have sensitivity in Mine (365 nm), G-line, H-line, UV, EUV, E-beam, X-ray, visible or other actinic radiation well known in the art used for photolithography.

Solvents useful in the current disclosure include esters, ethers, ether-esters, the gycols, ketones, keto-esters, hydrocarbons, aromatics, and halogenated solvents and combinations thereof, including propyleneglycolmonomethylether acetate (PGMEA) and ethyl lactate.

The photoresist compositions may also include a surfactant, an adhesion promoter, a dissolution inhibitor, a dye or combinations thereof.

Ranges of the components of the photoresist composition include 25%-86% polymer; 4.0%-20.0% flexibilizer when present; 0.01%-2.0% photoacid generator (amount based on polymer); dissolution modifier, when present: 0.8%-2.0%; adhesion promoter, when present: 0.8%-1.5%, and surfactant, when present: 0.04%-0.13%.

Disclosed and claimed herein are methods of patterning the photoresist compositions of the above materials and above photoresists, by 1) providing a substrate, 2) applying the photoresist compositions of any of the above disclosed photoresist compositions to a desired wet thickness, 3) heating the coated substrate to remove a majority of the solvent to obtain a desired thickness, 4) imagewise exposing the coating to actinic radiation, 5) post exposure baking the imaged coating, 6) removing the unexposed areas of the coating, and 7) optionally heating the remaining coating.

Substrates useful in the current disclosure are those that are typically used in IC technology, such as, for example, a silicon wafer, as is, or the wafer may be treated with a number of coatings including adhesion promotors, metal layers, oxide layers and the like. The wafer may also contain prefabricated structures such as other dielectric layers, or metal layers such as for example, copper, aluminum, gold, and the like, including copper panels, copper foil, silver coated substrates, and gold coated substrates The current compositions are then applied to the surface of the substrate and coated using such techniques as, for example, spin coating, ink-jet coating, curtain coating, brush coating, dip coating and the like. Coating thicknesses may be between 1-50 microns. Solvent is removed to less than about 92% by heating, such as, for example 90-110° C. for 1-3 minutes.

Once the substrate has been coated, the photoimageable composition is exposed with actinic radiation to provide a desired pattern. The radiation may be I-line (365 nm), G-line, H-line, UV, EUV, E-beam, visible or other actinic radiation well known in the art used for photolithography. The exposure dose may range from 1-50 mJ/cm². The coating may then optionally post exposure baked at between about 90° C. and about 125° C. for between 30 sec and 2 minutes.

The photoacid that is generated during exposure may fully or partially breakdown the acid labile crosslinks, such as, for example, between about 10% to about 90% depending on the amount of acid and additional processing steps. It is not essential that the both ends of the crosslinker breakdown for the exposed areas to be developable.

The unexposed areas are then removed using a suitable developer, aqueous or organic solvent, such as for example an aqueous alkaline developer, such as, for example tetramethylammonium hydroxide, at concentration between about 0.5% and 5%, such as for example 2.38%. The developer may be at room temperature or heated. The resulting structure may optionally be heated to increase the cure, for example, 175-250° C. for 1-5 minutes.

### EXAMPLES

### Example 1

To 100 equivalents (eq) of polyhydroxystyrene (PHS) MW=5700 daltons, polymer segments, dissolved in 1000 eq of propylene glycol monomethyl ether acetate (PGMEA), was added 1.5 equivalents of 1,4-bis(vinyloxymethylene) cyclohexane (difunctional vinyl ether crosslinker), 30 equivalents of vinyl ethyl ether (mono-functional vinyl ether) and 0.03 eq of p-toluene sulfonic acid. The admix was mixed for 2 hrs at ambient temperature. The amount of reaction with the hydroxy group of the PHS was determined to be 36 mol %. The molecular weight was determined to be 25000 daltons.

### Example 2

Cross-linked acetalized PHS dissolved in PGMEA from Example 1 was blended with a copolymer of styrene and PHS dissolved in PGMEA at a wt % blend ratio of 50:50. Aromatic sulfonium based PAG 290 dissolved in cyclopentanone, was added at 0.55 wt % of the polymer blend. A proton quenching agent, triphenylphosphine oxide, TPPO dissolved in cyclopentanone was added at 0.075 wt % of the polymer blend.

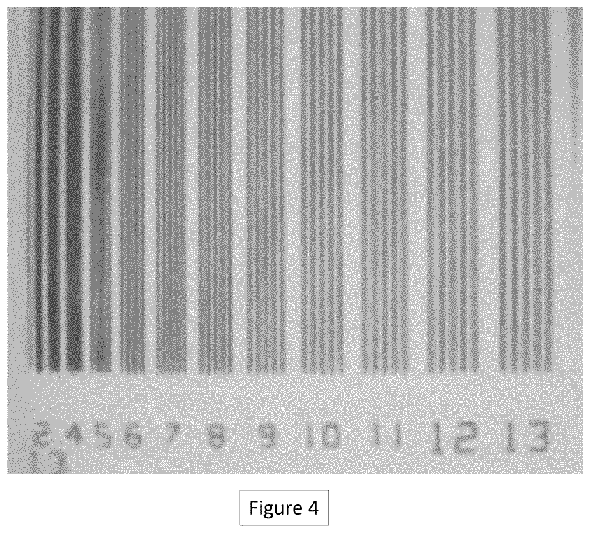

The composition was spin coated onto a HMDS treated silicon wafer and dried at 110° C. for 2 minutes to a dried coating of approximately 20 microns. The dried coated was exposed to 75 mJ/cm² i-line radiation and developed with 2.38% TMAH developer to provide a clean straight sidewalled photopattern with a line and space aspect ratio of approximately 3.5:1, See FIG. 4.

### Example 3

The process of Example 2 was repeated with elimination of the exposure. When treated with the 2.38% TMAH developer 0% film loss of the unexposed coating resulted.

### Example 4

Example 2 was repeated substituting the sulfonium based PAG 290 with a nonane sulfonium based ILP-113N PAG dissolved in cyclopentanone was added at 0.35 wt % of the polymer blend.

The composition was spin coated onto a HMDS treated silicon wafer and dried at 110° C. for 2 minute to a dried coating of approximately 20 microns. The dried coating was exposed to 75 mJ/cm² i-line radiation and developed with 2.38% TMAH developer. The sidewall profiles were tapered and had varying degrees of undercut at the base of the feature.

Repeating the above process, but with an increase of exposure result in 100% loss of the photo pattern washing the film away.

### Example 5

Example 2 was repeated substituting the sulfonium based PAG 290 with a camphor sulfonium based PA-480 PAG dissolved in cyclopentanone was added at 0.35 wt % of the polymer blend.

The composition was spin coated onto a HMDS treated silicon wafer and dried at 110° C. for 2 minute to a dried coating of approximately 20 microns. The dried coating was exposed to 75 mJ/cm2 i-line radiation and developed with 2.38% TMAH developer. The sidewall profiles were tapered and had and varying degree of undercut at the base of the feature.

### Example 6

Cross-linked acetalized PHS dissolved in PGMEA from Example 1 was blended with a copolymer of styrene and PHS dissolved in PGMEA at a wt % blend ratio of 65:35. Aromatic sulfonium based PAG 290 dissolved in cyclopentanone, was added at 0.55 wt % of the polymer blend.

The composition was spin coated onto a HMDS treated silicon wafer and dried at 110° C. for 2 minutes to a dried coating of approximately 20 microns. The dried coated was exposed to 75 mJ/cm² i-line radiation and developed with 2.38% TMAH developer to provide a clean straight sidewalled photopattern with a line and space aspect ratio of approximately 3.5:1. See FIG. 4.

### Example 7

Cross-linked acetalized PHS dissolved in PGMEA from Example 1 was blended with an aromatic sulfonium based PAG 290 dissolved in cyclopentanone, was added at 0.55 wt % of the polymer blend. A proton quenching agent, triphenylphosphine oxide, TPPO dissolved in cyclopentanone was added at 0.075 wt % of the polymer blend.

The composition was spin coated onto a HMDS treated silicon wafer and dried at 110° C. for 2 minutes to a dried coating of approximately 20 microns. The dried coating was exposed to 75 mJ/cm² i-line radiation and developed with 2.38% TMAH developer to provide a photopattern with a line and space aspect ratio of approximately 1:1 with residue apparent throughout the patterned areas.

### Example 8

Cross-linked acetalized PHS dissolved in PGMEA from Example 1 was blended with a copolymer of styrene and PHS dissolved in PGMEA at a wt % blend ratio of 75:25. Aromatic sulfonium based PAG 290 dissolved in cyclopentanone, was added at 0.55 wt % of the polymer blend. A proton quenching agent, triphenylphosphine oxide, TPPO dissolved in cyclopentanone was added at 0.075 wt % of the polymer blend.

The composition was spin coated onto a HMDS treated silicon wafer and dried at 110° C. for 2 minutes to a dried coating of approximately 20 microns. The dried coated was exposed to 75 mJ/cm² i-line radiation and developed with 2.38% TMAH developer to provide a clean straight sidewalled photopattern with a line and space aspect ratio of approximately 5:1.

### COMPARATIVE EXAMPLE

Example 2 was repeated using only PHS at MW of 5700. When processed the film loss was determined to be 4200 Å/sec such that 50% of the coating would be dissolved away after 30 seconds.

Thus, it can be seen that judicial formulation of the components of the compositions of the current disclosure utilizing the internally crosslinked and acetalized polymers of the current disclosure can result in outstanding photoresist pattern formation.

We claim:

1. A polymer comprising two or more polymer segments, each polymer segment comprising hydroxystyrene in the polymer segment backbone, wherein the polymer segments are internally crosslinked via hydroxy functionalities of the hydroxystyrenes by at least one di-functional crosslinker to form a polymer comprising acid labile crosslinks.

2. The polymer of claim 1, wherein the acid labile crosslinks are acetals, ketals, carboxylic acid esters, silyl esters, methylene-ethers, ortho-esters crosslinks or combinations thereof.

3. The polymer of claim 2, wherein the di-functional crosslinker is a difunctional aliphatic group, a cycloaliphatic group, an aryl group, a fused aryl group, an aliphatic heterocyclic group, an aromatic heterocyclic group, or combinations thereof.

4. The polymer of claim 2, wherein the polymer segments further comprise at least one additional monomer unit in the polymer segment backbone.

5. The polymer of claim 4, wherein the at least one more additional monomer unit is a substituted or unsubstituted styrene monomer unit, a substituted or unsubstituted hydroxystyrene monomer unit, or both.

6. The polymer of claim 5, wherein the hydroxy functionality of the additional hydroxystyrene monomer unit is further functionalized by a mono acetal or ketal.

7. The polymer of claim 6, wherein the percent of hydroxy functionalities that are crosslinked is between about 2% and about 5%.

8. The polymer of claim 7, wherein the percent of hydroxy functionalities are reacted with mono acetal or ketal is between about 20% and about 40%.

9. The polymer on claim 8, wherein the molecular weight is between about 10,000 and about 50,000 Daltons.

10. A photoresist composition comprising:
a. the polymer of claim 1,
b. at least one photoacid generator
c. at least one solvent

11. The photoresist composition of claim 10, further comprising at least one of a non-crosslinked polymer, oligomer, or copolymer, wherein the at least one non-crosslinked polymer, oligomer or copolymer has selected solubility in alkaline developer.

12. The photoresist composition of claim 11, wherein the at least one polymer, oligomer or copolymer is comprised of monomers chosen from styrene, hydroxystyrene, acrylic acid, acrylic esters, phenols, polyhydroxyphenyls, ethers, hydroxystyrene esters, or combinations thereof.

13. The photoresist composition of claim 11, wherein the at least one photoacid generator comprises an onium salt compounds, a sulfone imide compound, a halogen-containing compound, a sulfone compound, a sulfonate ester compound, a quinine-diazide compound, or a diazomethane compound.

14. The photoresist composition of claim 11, wherein the at least one solvent comprises esters, ethers, ether-esters, ketones, keto-esters, hydrocarbons, aromatics, and halogenated solvents and combinations thereof.

15. The photoresist composition of claim 11 further comprising a surfactant, an adhesion promoter, a dissolution inhibitor, a dye or combinations thereof.

16. (canceled)

17. (canceled)
